(19) United States
(12) Patent Application Publication
(10) Pub. No.: US 2024/0076521 A1
(43) Pub. Date: Mar. 7, 2024

(54) POLISHING LIQUID FOR POLISHING COMPOUND SEMICONDUCTOR SUBSTRATE

(71) Applicant: DISCO CORPORATION, Tokyo (JP)

(72) Inventors: Ayumu SAKAI, Tokyo (JP); Katsuyoshi KOJIMA, Tokyo (JP)

(21) Appl. No.: 18/461,077

(22) Filed: Sep. 5, 2023

(30) Foreign Application Priority Data
Sep. 7, 2022 (JP) 2022-141942

(51) Int. Cl. C09G 1/02; C09K 3/14

(52) U.S. Cl. CPC C09G 1/02; C09K 3/1409; B24B 37/042

(57) ABSTRACT

A polishing liquid for polishing a compound semiconductor substrate includes an aqueous solution in which a permanganate is dissolved, and abrasive grains which are dispersed in the aqueous solution and an electrokinetic potential (zeta potential) of which is plus. Preferably, the polishing liquid has a pH of 3 to 7. In addition, preferably, a concentration of the permanganate is not less than 2.5 wt %, and a concentration of the abrasive grains is not less than 4.5 wt %. Besides, preferably, the abrasive grains include silica grains having an average primary grain diameter of 12 nm to 60 nm.

### BACKGROUND OF THE INVENTION

### Field of the Invention

The present invention relates to a polishing liquid for polishing a compound semiconductor substrate.

### Description of the Related Art

In recent years, attention has been paid to a power device that has a high voltage resistance and is able to control a large current as compared to conventional devices formed by use of a silicon single crystal substrate. The power devices are formed, for example, on one surface side of a silicon carbide (SiC) single crystal substrate. It has been known that, prior to the formation of the devices on the one surface side of the SiC single crystal substrate, chemical mechanical polishing (CMP) is applied to the one surface side (see, for example, Japanese Patent Laid-open No. 2012-253259). In the polishing method described in Japanese Patent Laid-open No. 2012-253259, in a state in which the SiC single crystal substrate is held under suction by a chuck table, the SiC single crystal substrate is polished while a polishing liquid is supplied between a fixed abrasive grain pad and the SiC single crystal substrate.

It is particularly described in Japanese Patent Laid-open No. 2012-253259 that a highest polishing rate can be realized by use of an acidic polishing liquid in which potassium permanganate (KMnO₄) and ammonium cerium nitrate ((NH₄)₂Ce(NO₃)₆) are dissolved. Incidentally, at the time of performing CMP, a polishing pad not including abrasive grains may be used in place of the fixed abrasive grain pad. In this case, polishing is conducted while a polishing liquid containing abrasive grains is supplied between the polishing pad and the polished surface. As the abrasive grains contained in the polishing liquid, for example, abrasive grains formed of silica (silicon dioxide) are used.

### SUMMARY OF THE INVENTION

However, functional groups such as hydroxyl groups (namely, OH groups) are present on the surfaces of the silica abrasive grains, and these functional groups function as anions in the polishing liquid, so that, when the silica abrasive grains are mixed into the acidic polishing liquid, electric charges on the abrasive grains may be canceled by cations in the polishing liquid, and the abrasive grains may be aggregated and precipitated. In other words, there is a problem that the abrasive grains cannot be favorably dispersed in the polishing liquid. The present invention has been made in consideration of such a problem, and it is an object of the invention to favorably disperse the abrasive grains in a polishing liquid for polishing a compound semiconductor substrate such as a SiC single crystal substrate.

In accordance with an aspect of the present invention, there is provided a polishing liquid for polishing a compound semiconductor substrate. The polishing liquid includes an aqueous solution in which a permanganate is dissolved, and abrasive grains which are dispersed in the aqueous solution and an electrokinetic potential (zeta potential) of which is plus.

Preferably, the polishing liquid has a pH of 3 to 7.

Preferably, a concentration of the permanganate in the polishing liquid is not less than 2.5 wt %, and a concentration of the abrasive grains in the polishing liquid is not less than 4.5 wt %.

Preferably, the abrasive grains include silica grains having an average primary grain diameter of 12 nm to 60 nm.

The grain diameter of the abrasive grains contained in the polishing liquid for polishing a compound semiconductor substrate according to the aspect of the present invention is sufficiently greater than the diameter of anions present in the aqueous solution in which the permanganate is dissolved. Further, the electrokinetic potential of the abrasive grains is plus, and the number of electric charges on a slide plane where the electrokinetic potential is defined is predominantly greater than the number of the anions present in the aqueous solution. Hence, even when the abrasive grains are mixed into the aqueous solution in which the permanganate is dissolved, the abrasive grains repel one another on an electric charge basis, so that a favorable dispersed state can be realized in the polishing liquid.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a partly sectional side view of a polishing apparatus;

FIG. 2 depicts results of an experiment in which the concentration of abrasive grains was varied stepwise, with the concentration of sodium permanganate fixed; and

FIG. 3 depicts results of an experiment in which the concentration of sodium permanganate was varied stepwise, with the concentration of abrasive grains fixed.

### DETAILED DESCRIPTION OF THE PREFERRED EMBODIMENT

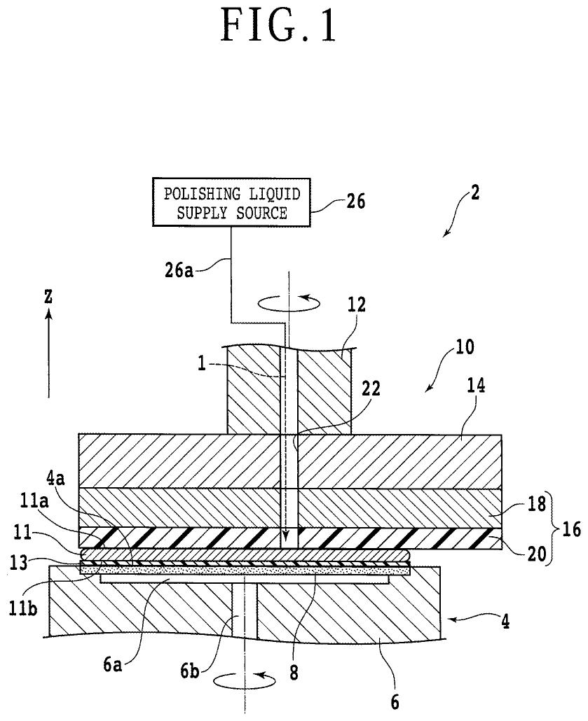

An embodiment according to an aspect of the present invention will be described with reference to the attached drawings. First, a polishing liquid 1 (see FIG. 1) of the present embodiment will be described. The polishing liquid 1 includes an aqueous solution in which a permanganate is dissolved and abrasive grains (free abrasive grains) an electrokinetic potential (zeta potential) of which is plus. As the permanganate, there is used sodium permanganate (NaMnO₄), potassium permanganate (KMnO₄), or the like. Note that, as the permanganate, use of sodium permanganate which is higher in solubility in water than potassium permanganate is preferred. Other examples of the permanganate include permanganates containing a metallic cation such as silver permanganate (AgMnO₄), zinc permanganate (Zn(MnO₄)₂), magnesium permanganate (Mg(MnO₄)₂), calcium permanganate (Ca(MnO₄)₂), and barium permanganate (Ba(MnO₄)₂).

As the abrasive grains the electrokinetic potential (zeta potential) of which is plus, colloidal silica in a liquid dispersant (namely, silica in sol form) which has a plus potential in the vicinity of surfaces of grains (namely, which is surface cationic) is used. The silica grains are charged mainly minus in the liquid dispersant, but the surfaces of the silica grains are covered with an electrical layer (also called a fixed layer or a Stern layer) mainly having a plus charge. Further, on the outside of the fixed layer, a diffusion layer in which plus charges and minus charges are mixed is present.

When the silica grains move in the liquid dispersant, the silica grains move together with the fixed layer and an inside (namely, a fixed layer side) region of the diffusion layer. The boundary between the inside region of the diffusion layer that moves together with the silica grains and an outside region of the diffusion layer is called a slide plane (or a slip plane). The electrokinetic potential is defined as the potential at the slide plane in a case where the potential at an electrically neutral place sufficiently spaced from the silica grain is made to be a zero point. The electrokinetic potential can be determined by a known technique such as an electrophoretic light scattering (ELS) measuring method.

As the abrasive grains the electrokinetic potential of which is plus, for example, SNOWTEX (registered trademark in Japan) can be used. SNOWTEX is a sol in which nano-sized silica grains are dispersed in water, and is manufactured and sold by Nissan Chemical Corporation. Specifically, a sol having the trade name “ST-AK” (average primary grain diameter: 12 nm, solid content: 20 wt %), a sol having the trade name “ST-AK-L” (average primary grain diameter: 45 nm, solid content: 20 wt %), and a sol having the trade name “ST-AK-YL” (average primary grain diameter: 60 nm, solid content: 30 wt %) can be used. Note that the average primary grain diameters are the results of measurement by a specific surface area measuring method (BET method).

The polishing liquid 1 including the aqueous solution in which the permanganate is dissolved and the above-mentioned abrasive grains dispersed in the aqueous solution is weakly acidic with a pH (hydrogen ion exponent) of 3 to 7 (3≤pH≤7), and is used when polishing a compound semiconductor substrate (workpiece) 11, as depicted in FIG. 1. In other words, the polishing liquid 1 is for polishing a compound semiconductor substrate. The compound semiconductor substrate 11 is, for example, a single crystal substrate of silicon carbide (SiC), but may be a single crystal substrate of other compound semiconductors such as gallium nitride (GaN) and gallium arsenide (GaAs).

Particularly, the polishing liquid 1 is weakly acidic, and is used when polishing a compound semiconductor substrate. On the other hand, a silicon single crystal substrate is in general polished under a basic condition, and, hence, the polishing liquid 1 is generally not used for the polishing of the silicon single crystal substrate. Note that the polishing liquid 1 may further contain additives such as a pH adjustor, a viscosity adjustor, a rust preventive agent, or a preservative, in addition to the above-described aqueous solution in which the permanganate is dissolved and in which the abrasive grains having a plus electrokinetic potential are dispersed.

The grain diameter of the abrasive grains contained in the polishing liquid 1 is sufficiently greater than the diameter of anions present in the aqueous solution in which the permanganate is dissolved. Further, the electrokinetic potential of the abrasive grains is plus, and the number of charges on the slide surfaces of the abrasive grains where the electrokinetic potential is defined is predominantly greater than the number of anions present in the aqueous solution. Hence, even when the abrasive grains are mixed into the aqueous solution in which the permanganate is dissolved, the abrasive grains repel one another on an electric charge basis, and a favorable dispersed state can be realized in the polishing liquid.

Next, the mechanism when chemical mechanical polishing is applied to a SiC single crystal substrate which is the compound semiconductor substrate 11, by use of the polishing liquid 1 including the aqueous solution in which the permanganate is dissolved and in which silica abrasive grains having a plus electrokinetic potential are dispersed will be described. Note that the mechanism described below is an assumption by the present applicant, and the actual mechanism may differ therefrom. First, when the polishing liquid 1 is supplied to one surface 11a (see FIG. 1) of the compound semiconductor substrate 11, Si atoms on the one surface 11a side are oxidized by an oxidizing action of permanganic acid (namely, an oxidant), to form a silicon oxide (SiO₂) layer.

Thereafter, the SiO₂ layer is physically scraped off by the abrasive grains, and a new SiC crystal plane is thereby exposed. When the new SiC crystal plane is exposed, similarly, the formation of SiO₂ by oxidation and the physical scraping-off by the abrasive grains are alternately repeated. Note that, for the polishing on the one surface 11a side to be thus made to proceed by use of the polishing liquid 1, the ability of the polishing liquid 1 to oxidize the one surface 11a of the compound semiconductor substrate 11 should be exhibited.

In the present embodiment, the one surface 11a side is oxidized mainly by permanganic acid. The permanganic acid is stronger in oxidizing power when pH is low (namely, under an acidic condition) than when pH is high (namely, under a basic condition). In the present embodiment, the polishing liquid 1 is kept to be weakly acidic by the water-soluble compound of a weak acid and a transition metal element, and the oxidizing power of the permanganic acid can thereby be exhibited sufficiently as compared to the case under a basic condition.

Incidentally, it is considered that, in a case where an aqueous solution in which sodium permanganate and ammonium cerium nitrate are dissolved is used as in the conventional technology, permanganic acid oxidizes ammonium ions (NH₄⁺) and ammonia (NH₃), and the permanganic acid in the polishing liquid 1 is thereby consumed. Hence, it is considered that, since the amount of permanganic acid for oxidizing the one surface 11a side is decreased, the oxidizing power of the permanganic acid is relatively weakened. It is considered that, as it becomes difficult for oxidation on the one surface 11a side to proceed, the polishing rate is lowered.

On the other hand, the water-soluble compound of the present embodiment does not contain ammonium ions and ammonia, as mentioned above (namely, concentrations of ammonium ions and ammonia are substantially 0 wt %). Hence, as compared to the conventional polishing liquid having potassium permanganate and ammonium cerium nitrate, the concentrations of ammonium ions and ammonia contained in the polishing liquid 1 are not more than the concentration of permanganic acid or the concentration of the cations constituting the permanganate together with permanganic acid. For example, in the polishing liquid 1 of the present embodiment, the concentration of ammonium ions is not more than the lower limit of quantitative analysis by ion chromatography and is substantially 0 wt %. It is to be noted, however, that, since ammonium ions present in a clean room in which polishing is conducted may be dissolved in the polishing liquid 1 in a trace amount, the ammonium ions in the polishing liquid 1 may not perfectly be 0 wt %.

However, to the polishing liquid 1 of the present embodiment, basic substances and basic ions such as ammonia and ammonium ions are intentionally not added as raw material at the time of manufacture. Hence, in the polishing liquid 1, the oxidizing power of permanganic acid can be exhibited sufficiently as compared to the conventional polishing liquid.

Next, a polishing method for the compound semiconductor substrate 11 by use of the polishing liquid 1 will be described. First, a polishing apparatus 2 to be used will be described. FIG. 1 is a partly sectional side view of the polishing apparatus 2. Note that a Z-axis direction depicted in FIG. 1 is substantially parallel to the vertical direction. The polishing apparatus 2 has a disk-shaped chuck table 4. To a lower surface side of the chuck table 4, a rotary shaft (not illustrated) whose longitudinal direction is disposed along the Z-axis direction is connected. The rotary shaft is provided with a driven pulley (not illustrated).

In the vicinity of the chuck table 4, a rotational drive source (not illustrated) such as a motor is provided. An output shaft of the rotational drive source is provided with a driving pulley (not illustrated). An endless belt (not illustrated) is wrapped around the driving pulley and the driven pulley, and motive power of the rotational drive source is transmitted to the rotary shaft of the chuck table 4. When the rotational drive source is operated, the chuck table 4 is rotated around the rotary shaft. The chuck table 4, the rotational drive source, and the like are supported by a moving plate (not illustrated) which is movable along a predetermined direction (for example, an X-axis direction orthogonal to the Z-axis direction).

The moving plate is movable along the X-axis direction together with the chuck table 4, the rotational drive source, and the like by a ball screw type moving mechanism (not illustrated). The chuck table 4 has a disk-shaped frame body 6 formed of a ceramic. A disk-shaped recess is formed in an upper part of the frame body 6. A disk-shaped porous plate 8 formed of a porous ceramic or the like is fixed in the recess. An upper surface of the porous plate 8 and an upper surface of the frame body 6 are flush with each other, to form a substantially flat holding surface 4a.

The porous plate 8 is connected to a suction source (not illustrated) such as a vacuum pump through flow channels 6a and 6b formed inside the frame body 6. When the suction source is operated, a negative pressure is transmitted to the upper surface of the porous plate 8. The compound semiconductor substrate 11 is mounted on the holding surface 4a. To another surface 11b of the compound semiconductor substrate 11 depicted in FIG. 1, a circular protective tape 13 formed of resin is stuck to prevent contamination, shock, and the like.

The other surface 11b side of the compound semiconductor substrate 11 is held under suction by the holding surface 4a with the protective tape 13 therebetween such that the one surface 11a located on the side opposite to the other surface 11b is directed upward. On the upper side of the holding surface 4a, a polishing unit 10 is disposed. The polishing unit 10 has a cylindrical spindle housing (not illustrated). The longitudinal direction of the spindle housing is disposed substantially in parallel to the Z-axis direction. To the spindle housing, a ball screw type Z-axis direction moving unit (not illustrated) for moving the polishing unit 10 along the Z-axis direction is connected.

A part of a cylindrical spindle 12 is rotatably accommodated in the spindle housing. The longitudinal direction of the spindle 12 is disposed substantially in parallel to the Z-axis direction. A rotational drive source (not illustrated) such as a motor for rotating the spindle 12 is provided at a part on the upper side of the spindle 12. To a lower end part of the spindle 12, a central part of an upper surface of a disk-shaped mount 14 is connected. The mount 14 has a diameter larger than the diameter of the holding surface 4a. To a lower surface of the mount 14, a disk-shaped polishing tool 16 substantially equal in diameter to the mount 14 is mounted.

The polishing tool 16 has a disk-shaped base (also called a platen) 18 connected to the lower surface of the mount 14. The base 18 is formed of such metal as stainless steel. To a lower surface of the base 18, a polishing pad 20 substantially equal in diameter to the base 18 is fixed. The polishing pad 20 is formed of a rigid foamed polyurethane resin, but may be formed of other rigid foamed resins or a non-woven fabric in place of the rigid foamed polyurethane resin. Note that abrasive grains are not fixed in the polishing pad 20.

Radially central positions of the polishing pad 20, the base 18, the mount 14, and the spindle 12 are substantially coincident with each other, and a cylindrical through-hole 22 is formed in such a manner as to pass through these central positions. An upper end part of the through-hole 22 is connected to a polishing liquid supply source 26 through a conduit 26a. The polishing liquid supply source 26 includes a storage tank (not illustrated) for the polishing liquid 1, a pump (not illustrated) for feeding the polishing liquid 1 from the storage tank into the conduit 26a, and the like. The polishing liquid 1 supplied from the polishing liquid supply source 26 is supplied through the through-hole 22 to a central part of the polishing pad 20.

In polishing by use of the polishing apparatus 2, the chuck table 4 is rotated in a predetermined direction, and the spindle 12 is also rotated in a predetermined direction. The rotating speed is, for example, 500 rpm for the chuck table 4, and 495 rpm for the spindle 12 (namely, the polishing tool 16). By thus setting a speed difference in such a manner as to set the rotating speed of one of the chuck table 4 and the spindle 12 to an even number and set the rotating speed of the other to an odd number, it is possible to prevent the one surface 11a and the same region of the polishing pad 20 from keeping contact with each other for a predetermined time as in a case where the rotating speeds of the chuck table 4 and the spindle 12 are set equal. In addition, in the present embodiment, a polished surface (the one surface 11a) is directed upward (namely, face-up), and the polishing liquid 1 is supplied to the polished surface from above the polished surface. Hence, the polishing liquid 1 can suitably be supplied to the polished surface even if the rotating speed of the chuck table 4 is set in excess of 120 rpm.

On the other hand, in a case where the polished surface is directed downward (namely, face-down), the compound semiconductor substrate 11 is disposed at the position of the polishing pad 20, the polishing pad 20 is disposed at the position of the chuck table 4, and the polishing liquid 1 is supplied from above to a predetermined region of the polishing pad 20, the predetermined region being not in contact with the compound semiconductor substrate 11. However, in a case where the polished surface is thus directed downward (namely, face-down), when the rotating speed of the polishing pad 20 is set in excess of 120 rpm, the polishing liquid 1 supplied to the polishing pad 20 is scattered toward outside in the radial direction of the polishing pad 20 by a centrifugal force, so that the polishing liquid 1 is not suitably supplied to the polished surface. As a result, it is difficult for the polishing rate to be increased even if the rotating speed of the polishing pad 20 is raised (in other words, the polishing does not conform to the law of Preston).

In the present embodiment, since the face-up system is adopted, the polishing liquid 1 can suitably be supplied to the polished surface even when rotation at a high speed in excess of 120 rpm is conducted. In addition, the polishing rate can be increased as the rotating speeds of the chuck table 4 and the spindle 12 are raised. In other words, polishing in conformity with the law of Preston can be realized.

Note that, at the time of polishing, the chuck table 4 may be oscillated in a range of a predetermined distance along a predetermined direction (for example, the X-axis direction) by a moving mechanism. Specifically, an operation of moving the chuck table 4 by a predetermined distance in a +X direction and then moving the chuck table 4 by the predetermined distance in a −X direction is repeated. The predetermined distance is smaller than the radius of the compound semiconductor substrate 11, preferably smaller than 1/10 times the diameter of the compound semiconductor substrate 11. By thus oscillating the chuck table 4 at the time of polishing, there is obtained a merit that the ruggedness on the one surface 11a side can be reduced as compared to a case where the oscillation is not conducted.

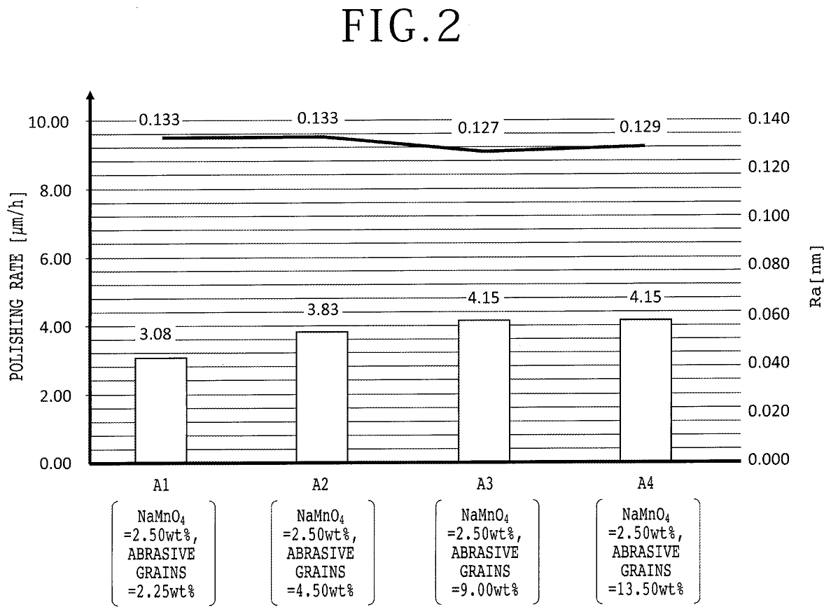

Next, results of an experiment in which a SiC single crystal substrate was polished by use of a polishing liquid 1 including an aqueous solution in which sodium permanganate (NaMnO₄) was dissolved and the above-mentioned ST-AK (silica abrasive grains having a plus electrokinetic potential) will be described with reference to FIG. 2. FIG. 2 depicts results of an experiment in which the concentration of sodium permanganate was fixed at 2.50 wt %, whereas the concentration of the abrasive grains was varied stepwise from 2.25 wt % to 13.50 wt %, and the polishing rate (μm/h) and the ruggedness (Ra (nm)) of the polished surface were measured. In the experiment, the polishing conditions were set as follows.
Rotating speed of chuck table 4: 500 rpm
Rotating speed of polishing pad 20: 495 rpm
Flow rate of polishing liquid: 0.15 L/min
Pressure from polishing pad 20: 73.5 kPa
Polishing time: 6 minutes (namely, 360 seconds)
Compound semiconductor substrate 11: SiC single crystal substrate
Diameter of compound semiconductor substrate 11: 4 inches (approximately 100 mm)
Polished surface: Si surface

A1 in FIG. 2 represents a polishing liquid 1 including an aqueous solution containing 2.50 wt % of sodium permanganate and 2.25 wt % of abrasive grains. To prepare this polishing liquid 1, for example, 250 g of sodium permanganate is dissolved in a sufficient amount of pure water, 1250 g of the above-mentioned ST-AK is further added thereto, then the solution is diluted with pure water to 10 L, and thereafter the solution is stirred at 100 rpm by use of a stirrer for 30 minutes. Note that A1 had a pH of 5.26 at 20.2° C. In a case where A1 was used, the polishing rate was 3.08 μm/h, and the ruggedness (Ra) of the one surface 11a after polishing was 0.133 nm. Note that Ra refers to arithmetic mean roughness. Ra is set according to JIS B 0601:2013, and refers to the mean of absolute values of height positions of an outline curve in a reference length.

A2 in FIG. 2 represents a polishing liquid 1 including an aqueous solution containing 2.50 wt % of sodium permanganate and 4.50 wt % of abrasive grains. For example, by use of 2250 g of ST-AK, A2 can be prepared by a process similar to that for A1. Note that A2 had a pH of 4.59 at 20.1° C. In a case where A2 was used, the polishing rate was 3.83 μm/h, and Ra of the one surface 11a after polishing was 0.133 nm.

A3 in FIG. 2 represents a polishing liquid 1 including an aqueous solution containing 2.50 wt % of sodium permanganate and 9.00 wt % of abrasive grains. For example, by use of 4500 g of ST-AK, A3 can be prepared by a process similar to that for A1. Note that A3 had a pH of 4.56 at 20.2° C. In a case where A3 was used, the polishing rate was 4.15 μm/h, and Ra of the one surface 11a after polishing was 0.127 nm.

A4 in FIG. 2 represents a polishing liquid 1 including an aqueous solution containing 2.50 wt % of sodium permanganate and 13.50 wt % of abrasive grains. For example, by use of 6750 g of ST-AK, A4 can be prepared by a process similar to that for A1. Note that A4 had a pH of 4.50 at 20.2° C. In a case where A4 was used, the polishing rate was 4.15 μm/h, and Ra of the one surface 11a after polishing was 0.129 nm.

In the polishing liquids 1 of A1 to A4, aggregation and sedimentation of the abrasive grains did not occur. In other words, in the polishing liquids 1, a favorable dispersed state of the abrasive grains could be realized. The present applicant considers the reason why the favorable dispersed state of the abrasive grains could be realized, as follows. The grain diameter of the abrasive grains contained in the polishing liquid 1 is sufficiently greater than the diameter of anions present in the aqueous solution in which the permanganate is dissolved. Further, the electrokinetic potential of the abrasive grains is plus, and the number of electric charges on the slide planes of the abrasive grains is predominantly larger than the number of anions present in the aqueous solution. Hence, even when the abrasive grains are mixed into the aqueous solution in which the permanganate is dissolved, the abrasive grains repel one another on an electric charge basis, so that a favorable dispersed state is realized in the polishing liquid 1.

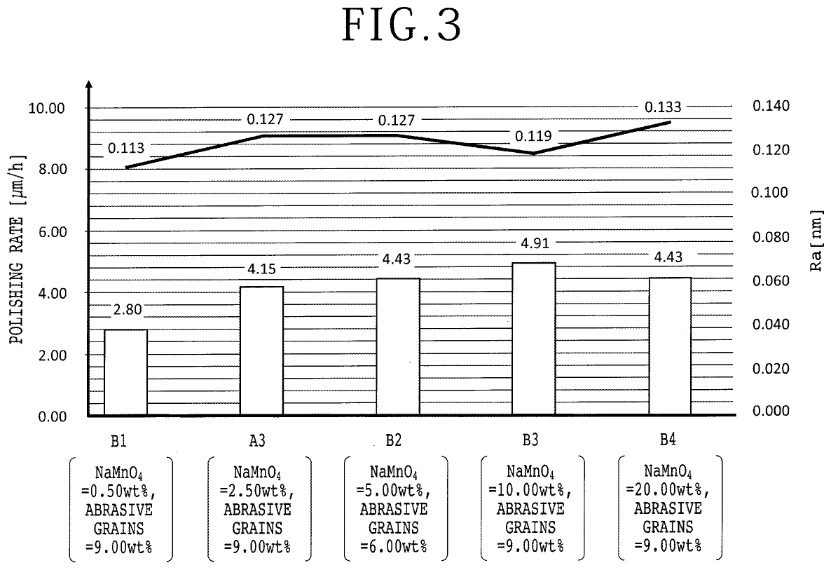

As depicted in FIG. 2, in the case where the concentration of sodium permanganate is fixed, the polishing rate reaches ceiling at a concentration of the abrasive grains of not less than 9.00 wt %; in view of this, next, the concentration of the abrasive grains was fixed at 9.00 wt %, and the concentration of sodium permanganate was varied. FIG. 3 depicts results of an experiment in which the concentration of the abrasive grains was fixed at 9.00 wt %, whereas the concentration of sodium permanganate was varied stepwise, and the polishing rate (μm/h) and the ruggedness (Ra (nm)) of the polished surface were measured. Note that A3 in FIG. 3 is the same as A3 in FIG. 2.

B1 in FIG. 3 represents a polishing liquid 1 including an aqueous solution containing 0.50 wt % of sodium permanganate and 9.00 wt % of the abrasive grains. By setting the amount of sodium permanganate used to be ⅕ times that for A1, B1 can be prepared by a process similar to that for A1. Note that B1 had a pH of 4.42 at 20.4° C. In a case where B1 was used, the polishing rate was 2.80 μm/h, and Ra of the one surface 11a after polishing was 0.113 nm.

B2 in FIG. 3 represents a polishing liquid 1 including an aqueous solution containing 5.00 wt % of sodium permanganate and 9.00 wt % of the abrasive grains. By setting the amount of sodium permanganate used to be two times that for A1, B2 can be prepared by a process similar to that for A1. Note that B2 had a pH of 4.80 at 20.1° C. In a case where B2 was used, the polishing rate was 4.43 μm/h, and Ra of the one surface 11a after polishing was 0.127 nm.

B3 in FIG. 3 represents a polishing liquid 1 including an aqueous solution containing 10.00 wt % of sodium permanganate and 9.00 wt % of the abrasive grains. By setting the amount of sodium permanganate used to be four times that for A1, B3 can be prepared by a process similar to that for A1. Note that B3 had a pH of 5.07 at 20.2° C. In a case where B3 was used, the polishing rate was 4.91 μm/h, and Ra of the one surface 11a after polishing was 0.119 nm.

B4 in FIG. 3 represents a polishing liquid 1 including an aqueous solution containing 20.0 wt % of sodium permanganate and 9.00 wt % of the abrasive grains. By setting the amount of sodium permanganate used to be eight times that for A1, B4 can be prepared by a process similar to that for A1. Note that B4 had a pH of 5.39 at 20.1° C. In a case where B4 was used, the polishing rate was 4.43 μm/h, and Ra of the one surface 11a after polishing was 0.133 nm. The polishing rate in the case of using B4 was lower than the polishing rate in the case of using B3. Note that, even when the concentration of sodium permanganate (the permanganate) is raised, the viscosity of the polishing liquid 1 is substantially not influenced. The present applicant presumes as follows: B4 is liable to oxidize the compound semiconductor substrate 11 as compared to B3, but the amount of the abrasive grains was relatively deficient, and the balance between the concentration of the oxidant and the concentration of the abrasive grains was lost, thereby lowering the polishing rate.

Also in the polishing liquids 1 of B1 to B4, a favorable dispersed state of the abrasive grains could be realized. In addition, since aggregation of the abrasive grains did not occur, in polishing by use of A1 to A4 and B1 to B4, scratches were substantially not formed on the polished surface. As clear from the experimental results in FIG. 2 and FIG. 3, when the concentration of sodium permanganate (the permanganate) is set not less than 2.5 wt % and the concentration of the abrasive grains having a plus electrokinetic potential is set not less than 4.5 wt %, polishing with a comparatively high polishing rate and Ra<0.2 nm and being substantially scratch-free can be realized while realizing a favorable dispersed state of the abrasive grains, so that high specification demands in post-steps after polishing can be fulfilled. Note that, taking the experimental results in FIG. 2 and FIG. 3 into account, the pH of the polishing liquid 1 may be 4 to 7.

Incidentally, the present applicant has confirmed that, in a polishing liquid in which an aqueous solution containing sodium permanganate and zirconyl acetate (ZrO(CH₃COO)₂) dissolved therein and abrasive grains having a plus electrokinetic potential are mixed, gelation of the polishing liquid and aggregation and sedimentation of the abrasive grains occur. Note that it is considered that a similar phenomenon occurs in cases where zirconyl carbonate or zirconyl nitrate is used in place of zirconyl acetate. The gelation of the polishing liquid is considered to arise from (i) continuous connection of the abrasive grains having a plus electrokinetic potential and zirconyl ions (ZrO²⁺) and polyvalent anions (CO₃²⁻) and (ii) a rise in viscosity due to an increase in the ratio of the solutes to the solvent, for example. Further, the present applicant has also confirmed that, also in a polishing liquid in which an aqueous solution containing zirconyl acetate dissolved therein and abrasive grains having a plus electrokinetic potential are mixed, gelation of the polishing liquid and aggregation and sedimentation of the abrasive grains occur.

Hence, it is considered that, even when abrasive grains having a plus electrokinetic potential are mixed into the acidic polishing liquid which is used in Japanese Patent Laid-open No. 2012-253259 mentioned above and in which potassium permanganate (KMnO₄) and ammonium cerium nitrate ((NH₄)₂Ce(NO₃)₆) are dissolved, gelation of the polishing liquid and aggregation and sedimentation of the abrasive grains occur. In other words, in cases where abrasive grains having a plus electrokinetic potential are mixed with the permanganate and the water-soluble compound (a complex salt such as ammonium cerium nitrate which is acidic when dissolved), which are conventionally known, a favorable dispersed state of the abrasive grains in the polishing liquid cannot be realized.

On the other hand, in the present application, the abrasive grains having a plus electrokinetic potential are mixed into an aqueous solution in which the permanganate is dissolved, and a favorable dispersed state of the abrasive grains in the polishing liquid 1 can thereby be realized through utilization of repulsion among the abrasive grains on an electric charge basis. In addition, the structures, methods, and the like concerning the above-described embodiment may appropriately be modified in carrying out the present invention, insofar as the modifications do not depart from the scope of the object of the invention. Note that, if the polishing liquid 1 is sprayed up to a region on a lower surface side of the polishing pad 20, the region being not in contact with the compound semiconductor substrate 11, from a spray nozzle disposed on the outside in the radial direction of the chuck table 4, in place of the supply of the polishing liquid 1 from the through-hole 22 at the time of polishing, clogging would occur at a discharge outlet of the spray nozzle or the like, which is unfavorable.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A polishing liquid for polishing a compound semiconductor substrate, the polishing liquid comprising:
an aqueous solution in which a permanganate is dissolved; and
abrasive grains which are dispersed in the aqueous solution and an electrokinetic potential (zeta potential) of which is plus.

2. The polishing liquid according to claim 1, wherein the polishing liquid has a pH of 3 to 7.

3. The polishing liquid according to claim 1,
wherein a concentration of the permanganate is not less than 2.5 wt %, and
a concentration of the abrasive grains is not less than 4.5 wt %.

4. The polishing liquid according to claim 1, wherein the abrasive grains include silica grains having an average primary grain diameter of 12 nm to 60 nm.
